(19) United States
(12) Patent Application Publication
(10) Pub. No.: US 2007/0286952 A1
(43) Pub. Date: Dec. 13, 2007

(54) Method and Structure of Strain Control of Sige Based Photodetectors and Modulators

(76) Inventors: Jifeng Liu, Cambridge, MA (US); Douglas D. Cannon, Somerville, MA (US); Kazumi Wada, Lexington, MA (US); Samerkhae Jongthammanurak, Cambridge, MA (US); David T. Danielson, Somerville, MA (US); Jurgen Michel, Arlington, MA (US); Lionel C. Kimerling, Concord, MA (US)

Correspondence Address: GOODWIN PROCTER LLP;PATENT ADMINISTRATOR, EXCHANGE PLACE, BOSTON, MA, 02109-2881, US

(21) Appl. No.: 10/566,686

(22) PCT Filed: Jul. 29, 2004
(86) PCT No.: PCT/US04/24747

§ 371 Date: Mar. 8, 2007

Related U.S. Application Data
(60) Provisional application No. 60/491,378, filed on Jul. 31, 2003.

(51) Int. Cl. H01L 21/20; C30B 25/18

(52) U.S. Cl. 427/209

(57) ABSTRACT

A SiGe or Ge structure comprises a substrate and a SiGe or Ge layer that is formed on a first surface of the substrate. A silicidation or germanide layer is formed on a second surface of the substrate so to increase the tensile strain of the SiGe or Ge layer on the first surface.

### PRIORITY INFORMATION

This application claims priority from provisional application Ser. No. 60/491,378 filed Jul. 31, 2003, which is incorporated herein by reference in its entirety.

### BACKGROUND OF THE INVENTION

The invention relates to the field of SiGe and Ge structures, and in particular to strain engineered SiGe and Ge structures using backside and/or frontside engineering, for example backside silicidation.

With the development of long-haul optical communications, dense wavelength division multiplexing (DWDM) has become a major technology to meet the ever increasing need for broader band and faster communications. In this technology, lights of different wavelengths are multiplexed and transmitted in a single fiber. As each wavelength is used as a channel for communications, the bandwidth of the fiber equals the bandwidth of each channel times the number of channels (wavelengths) in a single fiber. Obviously, the capacity of optical communications can be greatly enhanced in this way. Now the wavelength range used in telecommunications is expanding from C-band (1528-1561 mn) to also include L-band (1561-1620 nm). Correspondingly, related devices such as photo-detectors converting the optical signals to electrical ones should also meet the needs of the L-band. III-V semiconductors like InGaAs can be used in L-band photon detection, but these devices are not compatible with Si CMOS technology and require the growth on InP or GaAs substrates which leads to much higher costs.

In recent years, Ge photodetectors epitaxially grown on Si substrates have been developed as a promising candidate in near infrared photo-detection for telecommunications. Due to its direct band gap Eg^{Γ} of 0.8 eV, Ge shows efficient light absorption for wavelength λ<1550 nm. Ge epitaxial layers grown on Si substrates are compatible with existing Si technology (e.g. CMOS technology) and Ge p-i-n diodes with high responsivity (˜0.89 and 0.75 A/W at 1.3 and 1.55 μm, respectively) and fast response time (<200 ps) have been demonstrated. It has been reported a tensile strain induced direct band gap shrinkage from 0.8 eV to 0.77 eV in Ge epitaxial layers grown at high temperatures (700-800° C.) on Si(100), which enables efficient light detection up to about 1605 nm. However, this is still not enough to cover the whole L-band (1561-1620 nm) yet. Also the absorption coefficient around 1610 nm (corresponding to the band edge of the direct band gap of 0.2% tensile strained Ge) is relatively low (<10³/cm). Due to the strain relaxation at high temperature (>750° C.), it is impossible to further increase the tensile strain of Ge simply by going up to higher growth temperature or doing high temperature annealing after growth.

### SUMMARY OF THE INVENTION

According to one aspect of the invention, there is provided a method of forming a Ge-containing structure. The method includes providing a substrate having a first and second surface, and forming Ge-based layers over the first surface of the substrate. The method further includes forming a stress engineering layer over the second surface so as to increase the tensile strain of the Ge layer on the first surface.

According to another aspect of the invention, there is provided a SiGe-containing structure. The SiGe-containing structure includes a substrate and a SiGe layer that is over a first surface of the substrate. A silicide or germanide layer is over a second surface of the substrate so to increase the tensile strain of the SiGe layer on the first surface.

According to another aspect of the invention, there is provided a Ge-containing structure. The Ge-containing structure comprises a substrate and a Ge layer that is over a first surface of the substrate. A silicide or germanide layer is over a second surface of the substrate so as to increase the tensile strain of the Ge layer on said first surface.

### BRIEF DESCRIPTION OF THE DRAWINGS

FIGS. 1A-1C are schematic diagrams illustrating an exemplary process of backside silicidation in accordance with the invention;

FIG. 2 is a graph showing the XRD spectra of front side Ge (400) peaks of Ge/Si/Ge and Ge/Si/C54-TiSi₂ samples and demonstrating the enhancement of the tensile strain in the Ge structures by backside silicidation.

FIG. 3 is a graph showing the PR spectrum contributed by an optical transition of the direct band gap of Ge and demonstrates a shrinkage in the direct band gap of Ge after backside silicidation.

### DETAILED DESCRIPTION OF THE INVENTION

The invention uses backside and/or frontside strain engineering to further broaden the Ge absorption spectra.

The invention utilizes backside silicidation (e.g. of C54-TiSi₂ or CoSi₂) as a relatively simple solution to further increase the tensile strain in the front side Ge epitaxial layer. With this technique, the tensile strain in Ge or SiGe structures have been increased from 0.20% of the 800C as-grown sample to 0.24% after backside silicidation. This strain increase is suitable to further decrease the direct band gap of Ge to 0.765 eV, corresponding to 1620 nm and covering the whole L-band. For example, with 0.5 nm wavelength spacing in L-band, expanding the detection limit from 1605 to 1620 nm will enable another 30 channels for long-haul telecommunications. In addition, the backside silicide (e.g. C54-TiSi₂ or CoSi₂) layer forms a good electric contact of the device due to the low resistivity (14-20 μΩ·cm). Since the silicidation process is compatible with Si CMOS technology, this technique is promising to achieve low cost L-band photon detection completely with tensile strained Ge on Si.

Silicidation has been widely used in CMOS technology to decrease the contact resistance of source, drain and gate regions. C54-TiSi₂ has been the most commonly used silicide in ultra-large scale integrated circuits (ULSI) due to its low resistivity (14 μΩ·cm). Metal silicides are typically formed by depositing metal (Ti, Co, Ni, etc) on Si followed by silicidation annealing ranging from 600 to 900° C. It has also been found that the silicide layers (e.g. C54-TiSi₂) grown on Si show a large tensile stress, typically of about 2 GPa, mainly due to the thermal mismatch between silicide layer and Si substrate. Stress in the thin layer would induce a curvature in the Si substrate, described quantitatively by Stoney's equation:

$$κ = 6 {σ}_{film} \frac{{t}_{film}}{{t}_{sub}^{2} {M}_{Si}} \qquad Eq . 1$$

where κ is the curvature of the wafer, σ_{film} is the stress in the layer, M_{Si} is the biaxial modulus of the Si wafer, t_{film} and t_{sub} are the thickness of the layer and the substrate, respectively. Silicon substrate being the same, the curvature is determined by the product of the stress and the thickness of the layer σ_{film}t_{film}.

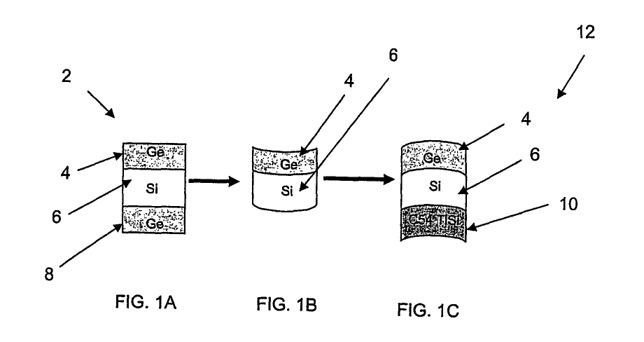

An exemplary process of backside silicidation, based on Ti, in accordance with the invention is schematically shown in FIGS. 1A-1C. As illustrated in FIG. 1A, Ge layers 4, 8 with a thickness of 1.3 μm are epitaxially grown on p⁺ Si(100) wafers 6 by ultra-high vacuum chemical vapor deposition (UHV-CVD) via a two step growth, where a ˜50 nm buffer layer is grown at 335° C. followed by 800C growth to deposit about 1 μm of Ge. In UHV-CVD process, Ge layers are equally deposited on both sides of the Si wafer so that the wafer is nominally flat, as shown in FIG. 1A. These samples 2 are referred to as Ge/Si/Ge hereinafter.

The Ge layer 8 on the backside is then removed by HF:H₂O₂:H₂O=1:1:10 solution at an etching rate of about 0.8 μm/min. During this etching process, the front side Ge layer 4 is protected by wax. After the etching, the sample is heated on a hot plate to melt the wax, followed by ultrasonic cleaning in acetone to clean the wax off. X-ray diffraction (XRD) confirms that the backside Ge layer 8 is completely removed while the front side Ge layer 4 is intact after the etching. Due to the tensile stress in Ge layer, after the removal of the backside Ge layer 8 the wafer 6 would be slightly concave, as shown in FIG. 1B. In the cases where the frontside Ge layer 2 is grown, in the first step above, by methods like molecular beam epitaxy (MBE), the resulting structure is in the form of Ge/Si with only one side of the Si wafer deposited with a Ge epitaxial layer. In this case, the Ge/Si structure does not need the above etching step.

Then a 1.2 μm Ti layer is deposited on the backside of the wafer by evaporation. The sample is then annealed at 850° C. for 45 min in Ar to form the silicidation layer 10. These samples 12 are now referred to as Ge/Si/C54-TiSi₂. The thickness of the C54-TiSi₂ layer 10, resulting from 1.2 μm Ti layer, is approximately 3 μm, which is greater than that of the frontside Ge layer 4. Since the stress in the silicide layer 10 (˜2 GPa) is also larger than that in the front side Ge layer 4 (˜0.28 GPa corresponding to 0.2% in-plane strain), one has σ_{TiSi}_{₂}t_{TiSi}_{₂}>>σ_{Ge}t_{Ge}. Therefore, the wafer 6 would be bent toward the backside and will change from a concave shape, as shown in FIG. 1B, to a convex shape, as shown in FIG. 1C.

Compared with the case in FIG. 1A, the tensile strain in the front side Ge layer 4 would be increased. Since the stress in Ge and C54-TiSi₂ layers 4, 10 are both thermal stress in nature, assuming both the Ge and the C54-TiSi₂ layers are relaxed at the silicidation temperature of 850° C. and using t_{TiSi}_{₂}, t_{Ge}>>t_{sub}, the in-plane strain increase in the Ge layer 4 induced by the backside silicidation can be derived as:

$$Δ {ɛ}_{1} ( Ge ) = \frac{3 Δ T}{{t}_{sub} {M}_{Si}} ( Δ {α}_{1} {t}_{{TiSi}_{2}} {M}_{{TiSi}_{2}} - Δ {α}_{2} {t}_{Ge} {M}_{Ge} ) \qquad Eq . 2$$

where ΔT is the difference between the silicidation temperature and room temperature, M_{Si}=180 GPa, M_{Ge}=140 GPa, and M_{TiSi}_{₂}=342 GPa are the biaxial modulus of Si(100), Ge(100) and polycrystalline TiSi₂, respectively; α stands for thermal expansion coefficient and Δα₁=α_{Si}−α_{TiSi}_{₂}=−10⁻⁵/K, Δα₂=α_{Si}−α_{Ge}=−2.5×10⁻⁶/K. The calculation with equation (2) shows that such a backside silicidation would increase the strain in the frontside Ge layer by about 0.03% after cooling down to room temperature.

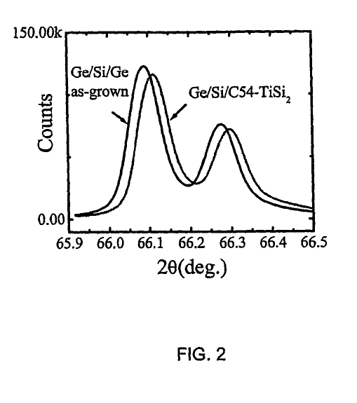

FIG. 2 shows the X-ray diffraction (XRD) spectra of front side Ge (400) peaks of Ge/Si/Ge and Ge/Si/C54-TiSi₂ samples. The strain in the structure is determined by comparing the Ge(400) peak positions with that of bulk Ge. For the as-grown sample, the strain is 0.204±0.004%. After the formation of the backside C54-TiSi₂ layer, the strain in the front side Ge layer increases by 0.036±0.006% to 0.240±0.004% compared with the as-grown sample. This experimental result agrees with our calculations based on Eq. (2), and demonstrates the strain increase in the front side Ge layer induced by backside silicidation.

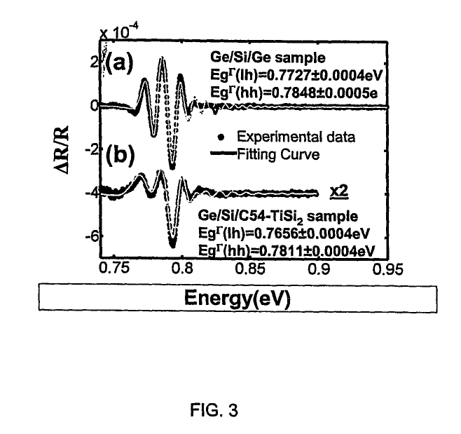

Photoreflectance (PR) is employed to investigate the change in Ge direct band gap after silicidation. The data is fitted with the generalized theory of Franz-Keldysh oscillations (FKO) to determine the direct band gaps of the Ge structures, as shown in FIG. 3. In PR the relative change in the reflectance ΔR/R induced by the modulation of pump laser is related to the perturbation of the complex dielectric function ε(ε=ε₁+iε₂) by
ΔR/R=aδε₁+bδε₂ Eq. 3
where a and b are Seraphin coefficients related to the unperturbed dielectric function, and δε₁ and δε₂ are the changes in the real and imaginary parts of the dielectric function, respectively. Near the fundamental band gap b≈0, so
ΔR/R≈aδε₁=aRe(δε) Eq. 4
in this case. The change in dielectric function in PR measurement can be described as
δε(E,F_{dc},F_{ac})=ε(E,F_{dc})−ε(E,F_{dc}−F_{ac})=Δε(E,F_{dc})−Δε(E,F_{dc}−F_{ac}) Eq. 5
where E is the photon energy, F_{dc} is the built-in electric field in the i-Ge epitaxial layer grown on p⁺ Si(100), F_{ac} is the electric field induced by the ac modulation of chopped pump laser, and
Δε(E,F)=ε(E,F)−ε(E,0) Eq. 6
For a three dimensional critical point like the optical transition of the direct band gap of Ge, one has:
Δε(E,F)=(B/E²)( [symbol] θ)^{1/2}(G(η)+iF(η)) Eq. 7
where B is a constant and the parameters [symbol] θ and η are given by: [symbol]
θ=(e² [symbol] ²F²/2m)^{2/3},η=(Eg−E−iγ/ [symbol] θ Eq. 8
In Eq. (8) m is the reduced effective mass in the direction parallel to the electric field, Eg is the energy gap of the transition and γ is the broadening factor. G(η) and F(η) are electro-optic functions given by:
G(η)=π[Ai′(η)Bi′(η)−ηAi(η)Bi(η)]+η^{1/2}H(η) Eq. 9
H(η)=π[Ai′²(η)−ηAi²(η)]−(−η)^{1/2}H(−η) Eq. 10
where Ai(η), Ai′(η), Bi(η), Bi′(η) are the Airy functions and their derivatives, and H(η) is the unit step function.

With Eqs. (3)-10), one is able to fit the PR spectrum contributed by an optical transition of band gap Eg. In this case, however, since the light and heavy hole valence bands of Ge become non-degenerate under biaxial stress, the spectra is the sum of contributions from light and heavy hole band transitions, characterized by band gaps Eg^{Γ}(lh) and Eg^{Γ}(hh), respectively. With this model, the fitting of the experimental data is shown in FIG. 3, from which one obtains Eg^{Γ}(lh)=0.7727±0.0004 eV, Eg^{Γ}(hh)=0.7848±0.0005 eV for Ge/Si/Ge sample and Eg^{Γ}(lh)=0.7656±0.0004 eV, Eg^{Γ}(hh)=0.7811±0.0004 eV for Ge/Si/C54-TiSi₂ sample. In both cases Eg^{Γ}(lh)<Eg^{Γ}(hh), so the value of the direct band gap of biaxial stressed Ge structure is determined by Eg^{Γ}(h). Note that in Ge/Si/C54-TiSi₂ sample Eg^{Γ}(lh) further decreases to 0.7656±0.0004 eV due to the strain enhancement by the backside silicide layer, which corresponds to 1620 nm. This result indicates that with backside silicidation method efficient light detection up to 1620 nm can be achieved.

The tensile strain in Ge epitaxial layer grown at 800° C. on Si(100) has been further increased by about 20% to 0.240% via backside C54-TiSi₂ silicidation, and the direct band gap further decreases to 0.7656 eV which corresponds to 1620 nm, covering the whole L-band in long-haul telecommunications. In device fabrication, the backside silicide layer can be grown during the back-end process, fully compatible with Si CMOS technology. It is contemplated that any intermediate layer may be placed between the substrate 6 of FIGS. 1A-C and the silicide layer 10 and/or between the substrate 6 and the Ge layer 4 without exiting from the present invention.

One drawback of current process is that the silicide layer required for strain increase in Ge is relatively thick, so the silicidation takes a relatively long time. This disadvantage can be improved by co-evaporation or co-sputtering of the metal (e.g. Ti or Co) and Si at 1:2 ratio so that the silicidation rate is no longer limited by metal-Si inter-diffusion. Rapid thermal annealing (RTA) may be applied to achieve the silicidation in that case and the dopant diffusion in the active region can be significantly decreased.

In an alternative process in accordance with the invention, the backside Ge may not necessarily be etched off since Ti can also form germanide (e.g. C54-TiGe₂) via solid phase reaction with Ge. As germanide, e.g. C54-TiGe₂, may have a larger thermal expansion coefficient than C54-TiSi₂ according to the trend in periodic table, it may also induce a larger tensile stress when grown on Si substrates. The backside silicidation provides a promising way to achieve complete L-band photo-detection with CMOS compatible, cost effective devices based on tensile strained epitaxial Ge on Si(100).

Based on the same spirit of backside silicidation, a front side engineering is also applicable to engineer the strain of SiGe or Ge structures. For example, an oxide or nitride layer (e.g. SiO₂, Si₃N₄, SiON or GeON) can be grown on top of Ge layer (e.g. Ge layer 4 of FIGS. 1A-C) followed by high temperature annealing (e.g. together with the backside silicidation annealing, for example, at 850° C. for 45 min in Ar). It is understood that any intermediate layer may be placed between the Ge layer 4 of FIGS. 1A-C and the oxide or nitride layer without exiting from the present invention. The oxide/nitride and Ge layer will relax during the high temperature annealing. Since oxide/nitride have less thermal expansion coefficients than Ge, they will be compressively stressed after cooling down. Correspondingly, the Ge layer will acquire more tensile strain due to the top oxide/nitride layer. The increase of strain in the Ge layer due to this frontside engineering is given by

$$Δ {ɛ}_{1} ( Ge ) = \frac{3 Δ T Δ {α}_{3} {t}_{oxide \text{/} nitride} {M}_{oxide \text{/} nitride}}{{t}_{sub} {M}_{Si}} , \qquad Eq . 11$$

where ΔT is the difference between the annealing temperature and room temperature; α stands for thermal expansion coefficient and Δα₃=α_{Si}−α_{oxide/nitride}≈2×10⁻⁶/K; t_{oxide/nitride} and t_{sub} are the thickness of the oxide/nitride layer and the substrate, respectively, and M_{Si} and M_{oxide/nitride} are the biaxial modulus of Si and oxide/nitride layers, respectively. The oxide/nitride layers also serve as surface passivation and antireflection coatings for Ge, which helps to decrease the dark current and increase the efficiency of the detector.

Another aspect of the present invention is a technique to reduce the strain in Ge or SiGe structures when needed. In that case, the silicide layer may be placed on the front side instead of the backside, using a process similar to the one described above. In this case, since silicide's thermal expansion coefficient is larger than that of Ge, upon cooling the silicide will induce some compressive stress to Ge and partially compensate for the tensile strain due to the Ge/Si thermal mismatch. Therefore the total tensile stress in Ge layer will be decreased. In other words, when a silicide layer is on the front side, the wafer will bend toward the front side just opposite to the case in FIG. 1C and the strain in the Ge structure will be decreased instead of increase

With the front side and backside strain engineering described above, a Si compatible L-band photodetector based on strained Ge on Si can be achieved (see FIG. 1C).

Although the present invention has been shown and described with respect to several preferred embodiments thereof, various changes, omissions and additions to the form and detail thereof, may be made therein, without departing from the spirit and scope of the invention.

What is claimed is:

1. A method of forming a Ge-containing structure, the method comprising the steps of:
providing a substrate having a first and a second surface;
forming a layer comprising Ge over said first surface; and
forming a stress engineering layer over said second surface,
wherein the stress engineering layer increases a tensile strain of the Ge-containing layer.

2. The method of claim 1, further comprising the step of:
forming a second layer comprising Ge over said second surface before forming the stress engineering layer.

3. The method of claim 2, wherein the step of forming the stress engineering layer comprises forming a germanide layer using the second Ge-containing layer formed over said second surface.

4. The method of claim 3, wherein the step of forming the germanide layer comprises depositing a metal layer on the second Ge-containing layer formed over said second surface and forming the germanide layer via solid phase reaction.

5. (canceled)

6. The method of claim 2, further comprising removing the second Ge-containing layer before forming the stress engineering layer.

7. (canceled)

8. The method of claim 2, wherein forming said first and second Ge-containing layers comprises using ultra-high vacuum chemical vapor deposition (UHV-CVD).

9. The method of claim 1, wherein said Ge-containing-layer comprises a Ge layer.

10. The method of claim 1, wherein said Ge-containing layer comprises a SiGe layer.

11. (canceled)

12. The method of claim 1, wherein said stress engineering layer allows a direct band gap of the Ge-containing layer of less than or equal to about 0.766 eV.

13. (canceled)

14. The method of claim 1 further comprising forming dielectric layer over said Ge-containing layer followed by high temperature annealing.

15. A SiGe-containing structure comprising;
a substrate,
a SiGe layer disposed over a first surface of said substrate, and
a stress engineering layer comprising at least one of silicide and germanide disposed over a second surface of said substrate,
wherein the stress engineering layer increases a tensile strain of the SiGe layer.

16. The SiGe-containing structure of claim 15, wherein said substrate comprises Si.

17. (canceled)

18. The SiGe-containing structure of claim 15, wherein said stress engineering layer comprises at least one of C54-TiSi₂, CoSi₂, and C54-TiGe₂.

19. The SiGe-containing structure of claim 15, wherein said stress engineering layer allows L-band photo-detection of said SiGe layer.

20. The SiGe-containing structure of claim 15 further comprising a dielectric layer disposed over said SiGe layer.

21. A Ge-containing structure comprising:
a substrate;
a Ge layer disposed over a first surface of said substrate; and
a stress engineering layer comprising at least one of silicide and germanide disposed over a second surface of said substrate,
wherein the stress engineering layer increases a tensile strain of the Ge layer.

22. The Ge-containing structure of claim 21, wherein said substrate comprises Si.

23. (canceled)

24. The Ge-containing structure of claim 21, wherein said stress engineering layer comprises at least one of C54-TiSi₂, CoSi₂, and C54-TiGe₂.

25. The Ge-containing structure of claim 21, wherein said stress engineering layer allows L-band photo-detection of said Ge layer.

26. The Ge-containing structure of claim 21 further comprising dielectric layer disposed over said Ge layer.

27. A photodetector comprising a Ge-containing structure produced in accordance to claim 1.

28. An optical modulator comprising a Ge-containing structure produced in accordance to claim 1.

29. The method of claim 1, wherein said substrate comprises Si.

30. The method of claim 29, wherein the step of forming the stress engineering layer comprises forming a silicide layer over said second surface.

31. The method of claim 30, wherein forming the silicide layer further comprises depositing a metal layer on said second surface of said substrate by evaporation and then annealing at high temperature.

32. The method of claim 29, wherein forming the silicide layer comprises simultaneously depositing a metal and silicon at a ratio of 1:2.

33. The method of claim 6, wherein removing said second Ge-containing layer comprises etching.
